(19) United States
(12) Patent Application Publication
(10) Pub. No.: US 2023/0087976 A1
(43) Pub. Date: Mar. 23, 2023

(54) NON-PLASMA ENHANCED DEPOSITION FOR RECESS ETCH MATCHING

(71) Applicant: Lam Research Corporation, Fremont, CA (US)

(72) Inventors: Ian John Curtin, Portland, OR (US); Douglas Walter Agnew, Portland, OR (US); Mamoru Imade, Osaka (JP); Joseph R. Abel, West Linn, OR (US); Awnish Gupta, Hillsboro, OR (US); Adrien Lavoie, Newberg, OR (US)

(21) Appl. No.: 17/802,525

(22) PCT Filed: Feb. 25, 2021
(86) PCT No.: PCT/US2021/019747

§ 371 Date: Aug. 25, 2022

Related U.S. Application Data
(60) Provisional application No. 62/982,500, filed on Feb. 27, 2020.

(51) Int. Cl. H01L 29/76

(52) U.S. Cl. CPC H01L 27/11582

(57) ABSTRACT

A NAND structure and method of fabricating the structure are described. A multi-layer ONON stack is deposited on a Si substrate and a field oxide grown thereon. A portion of the field oxide is removed, and high-aspect-ratio channels are etched in the stack. The channels are filled with a Si oxide using a thermal ALD process. The thermal ALD process includes multiple growth cycles followed by a passivation cycle. Each growth cycle includes treating the surface oxide surface using an inhibitor followed by multiple cycles to deposit the oxide on the treated surface using a precursor and source of the oxide. The passivation after the growth cycle removes the residual inhibitor. The Si oxide is recess etched using a wet chemical etch of DHF and then capped using a poly-Si cap.

### CLAIM OF PRIORITY

This application claims the benefit of priority to U.S. Patent Application No. 62/982,500, filed on Feb. 27, 2020, which is incorporated by reference herein in its entirety.

### TECHNICAL FIELD

The present disclosure generally relates to processing of semiconductor substrates. Some embodiments relate to filling and etching of materials on semiconductor substrates.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Semiconductor device fabrication for integrated circuitry is an increasingly complicated and involved set of processes to improve device performance and increase device density in the integrated circuits. The size of the smallest device feature over the generations of integrated circuits has shrunk from microns to about 22 nm. Numerous operations include a large number of depositions and etching of various insulating and dielectric materials are used to enable such a feature size to be reached. To achieve a reduction in feature size, in each integrated circuit generation, new fabrication processes and equipment are designed, as well as considerable time spent altering device and circuit layout. Newer integrated circuit generations have had to contend with other issues. These issues include limitations in the basic materials as well as the physics involved in the processes used to fabricate the integrated circuits.

### SUMMARY

Various embodiments described herein include a semiconductor device and a method of fabricating the semiconductor device. The method may comprise: etching high-aspect-ratio channels in a multi-layer stack disposed on a semiconductor substrate, the multi-layer stack comprising sets of oxide and non-oxide layers; filling each of the high-aspect-ratio channels with an oxide using a thermal atomic layer deposition (ALD) process; recess etching the oxide using a wet chemical etch to form recess-etched channels; and capping the recess-etched channels to refill an etched portion of the recess-etched channels with a conductive material.

In the method, filling each of the high-aspect-ratio channels with a Si oxide may further comprise: depositing the Si oxide in multiple blocks that each contains multiple growth cycles followed by a passivation operation, each of the growth cycles comprising: introduction of an inhibitor into a chamber in which the semiconductor substrate is disposed during an inhibition operation, followed by multiple thermal ALD deposition cycles.

The method may further comprise injecting H₂, O₂, Ar, and N₂ gasses and an aminosilane/BTBAS precursor during each ALD deposition cycle to deposit a sub-angstrom thickness of oxide per cycle.

In the method, the inhibitor may comprise multiple gasses that each act as an inhibitor.

In the method, the inhibition operation may be maintained for less than about 1 s.

The method may further comprise maintaining a temperature of a pedestal on which the semiconductor substrate is disposed during the growth cycle of about 550-650° C. and a pressure in the chamber of about 10-20 Torr.

The method may further comprise injecting H₂, O₂, Ar, and N₂ gasses during the passivation operation to remove residual inhibitor and passivate an exposed surface of the Si oxide in each of the high-aspect-ratio channels, the passivation operation maintained between under one minute and about two minutes.

The method may further comprise purging the chamber of gasses used in each growth cycle after the inhibition operation, before and after the thermal ALD deposition cycles associated with the inhibition operation, and after the passivation operation.

In the method, filling each of the high-aspect-ratio channels with a Si oxide may further comprise: depositing a first thermal Si oxide ALD liner layer within each of the high aspect-ratio-channels to form a liner layer prior to depositing the Si oxide in a first of the blocks; and depositing a second thermal Si oxide ALD liner layer after depositing the Si oxide within each of the high-aspect-ratio channels after a last of the blocks.

The method may further comprise for filling each of the high-aspect-ratio channels with the Si oxide: determining a number of blocks, a number of growth cycles within each block and a number of thermal ALD deposition cycles within each growth cycle, at least one of which depends on critical dimensions of each of the high-aspect-ratio channels as well as a quality of a structure in which the Si oxide is to be deposited.

In the method, recess etching the Si oxide may further comprise: etching the Si oxide using a dilute HF (DHF) etch of about 100:1 HF:H₂O, the Si oxide having a relatively constant etch rate along a width and depth of each of the high-aspect-ratio channels.

In the method, capping the recess-etched channels may further comprise: depositing polycrystalline Si (poly-Si) in the recess-etched channels using plasma-enhanced chemical vapor deposition.

The method may further comprise growing a field oxide on the multi-layer stack prior to forming the high-aspect-ratio channels; and planarizing the poly-Si to expose the field oxide, a top surface of the field oxide and a top surface of the poly-Si in each of the high-aspect-ratio channels lying in a plane after planarization of the poly-Si.

The method may further comprise depositing a sufficient amount of the Si oxide to cover the field oxide; and planarizing the Si oxide prior to recess etching the Si oxide such that a top surface of the field oxide and a top surface of the Si oxide in each of the high-aspect ratio-channels lie in a plane after planarization of the Si oxide.

The method may further comprise depositing alternating SiO2 and SiN layers as the multi-layer stack.

The method the recess etching of the Si oxide may avoid etching of the Si oxide using a vapor etch.

A 3D NAND device may comprise: a multi-layer stack disposed on a semiconductor substrate, the multi-layer stack comprising pairs of layers of alternating materials and having a plurality of high-aspect-ratio channels disposed therein; a field oxide disposed on the multi-layer stack; a thermal atomic layer deposition (ALD) Silicon (Si) oxide disposed within each of the high-aspect-ratio channels, the Si oxide wet chemical etched such that a surface of the Si oxide is beneath a bottom of the field oxide; and a polycrystalline Si (poly-Si) cap disposed within each of the high-aspect-ratio channels on the Si oxide.

The pairs of layers of the multi-layer stack may comprise a SiO2 layer and a SiN layer.

A depth of each of the high-aspect-ratio channels may be between about 4 and about 8 microns and a width of each of the high-aspect-ratio channels is between about 50 nm and 100 nm.

A depth of the poly-Si cap in each of the high-aspect-ratio channels may be about 1-4% of a depth of the high-aspect-ratio channels.

### DESCRIPTION OF THE DRAWINGS

Some embodiments are illustrated by way of example and not limitation in the views of the accompanying drawings. Corresponding reference characters indicate corresponding parts throughout the several views. Elements in the drawings are not necessarily drawn to scale. The configurations shown in the drawings are merely examples and should not be construed as limiting the scope of the disclosed subject matter in any manner.

FIGS. 1A-1D are diagrams showing a gapfill structure, according to an example embodiment.

FIG. 2 is a schematic diagram showing a method of fabricating a structure, according to an example embodiment.

FIG. 3 is a diagram showing etch uniformity within the channel shown in FIG. 1A, according to an example embodiment.

FIG. 4 shows a flowchart of fabrication of the structure shown in FIG. 1, according to an example embodiment.

FIG. 5 is a block diagram of a machine, according to an example embodiment.

### DESCRIPTION

The description that follows includes systems, methods, techniques, instruction sequences, and computing machine program products that embody illustrative embodiments of the present disclosure. In the following description, for purposes of explanation, numerous specific details are set forth in order to provide a thorough understanding of example embodiments. It will be evident, however, to one skilled in the art that the present inventive subject matter may be practiced without these specific details.

To create various types of semiconductor devices and integrated circuits, such as NAND memory structures, multiple processing operations may be used. Such processes may include, for example, deposition of multiple (e.g., for conductive and/or dielectric layers to form a multilayer film stack, vertical etching of the stack into a high aspect ratio channel, and filling of the channel. Process variability on both the horizontal and vertical planes, however, may result in variation in processing (e.g., filling or planarization) of one layer to be transferred and magnified in subsequent layers. This may compound errors and lead to poor device performance and low product yield. In particular, some of the processes involved in creation of such devices may rely on etching trenches or channels in the films so that the channels each have a high aspect ratio (i.e., a high ratio of channel depth to opening) and then filling the channels. However, filling a high aspect ratio channel may result in a material that is not uniformly distributed within the channel. This, in turn, may result in a variation in the characteristics of the filling material with depth within the channel. The variation may further affect etching within the channel due to the variation in composition of the material within the channel, as well as the depth-dependent ability of the etch to react with the material. All of the above may lead to reliability and performance problems. Thus, tight control of such processes, as well as in the etching and fill of such layers, may be desirable.

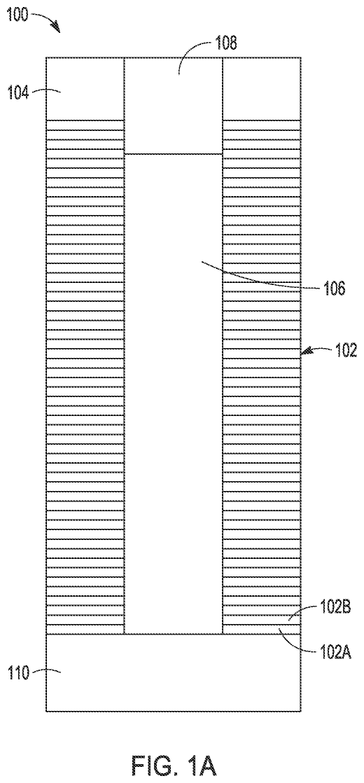

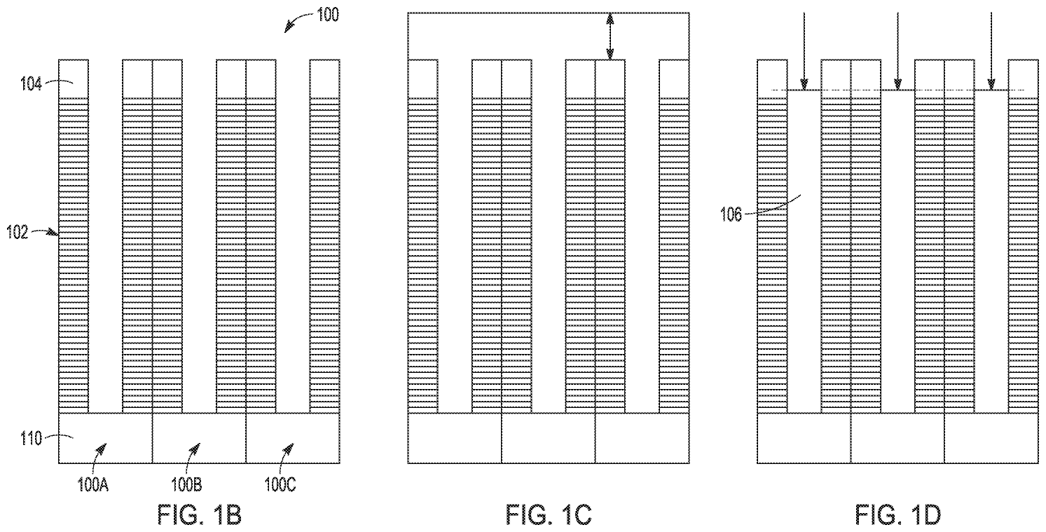

FIGS. 1A-1D show a gapfill structure, according to an example embodiment. The gapfill structure 100 shown in FIG. 1A may be a 3D NAND structure, for which one general process is described—other operations may be present but are not described for convenience. NAND is a Boolean operator that provides a value zero if and only if all the operands have a value of one, and otherwise has a value of one (equivalent to NOT AND). Although not described, cleaning operations may be provided between some or all of the operations described. Such cleaning operations may include the use of an RCA clean and deionized water rinse, followed by blow-drying the structure (rinsing using solvents and acids, such as hydrofluoric (HF) acid, may also be used). In particular, FIG. 1A shows a cell that includes a multilayer film stack 102 (hereinafter referred to as stack 102) grown on a wafer 110, such as a semiconductor or insulating substrate (e.g. a Si substrate). A semiconductor or insulating substrate is a support material upon which or within which elements of a semiconductor device are fabricated or attached. One such substrate may be, for example, a Si substrate with a thickness of about 300 mm. The stack 102 may be deposited using different processes, such as plasma-enhanced chemical vapor deposition (PECVD) or plasma-enhanced atomic layer deposition (PEALD). That is, ALD is a thin-film deposition technique based on the sequential use of a gas-phase chemical process using two or more precursors or reactants. These precursors may react with the surface of a material one at a time in a sequential, self-limiting, manner. A thin film may be slowly deposited through repeated exposure to separate precursors. The deposited films 102a, 102b may comprise pairs of individual layers: including oxide/nitride (ONON), oxide/polycrystalline Si (OPOP) or oxide/metal (OMOM). Polycrystalline silicon may be silicon with many single-crystal regions of different sizes and orientations. The oxide may be SiO₂ for example, the nitride may be SiN for example, and the metal may be W, Co, and/or Mo for example. The thickness of each film 102a, 102b may be the same for the same type of film or for all films and may be dependent on the device fabricated. Each film may be about 25-30 nm, for example, and thus each pair of films (e.g., ON) may be about 50-60 nm, for example. This set of films, however, is merely exemplary—other oxides, nitrides and metals may be used.

Once the stack 102 is deposited, a field dielectric 104 may be deposited on the stack 102 to protect the surface of the stack 102. A field dielectric, in some embodiments, may be a relatively thick dielectric formed to passivate and protect semiconductor surface outside of active device area. For example, the field dielectric 104 may be an oxide layer, such as SiO₂, about 100-150 nm (or up to about 500 nm). The field dielectric 104 may be formed, for example, by wet oxidation.

The field dielectric 104 over the area where the channel is to be formed may then be removed, which may expose the stack 102. A photolithographic process may be used to deposit and pattern photoresist to expose the area of the stack 102 in which the channel is to be formed. An etch may be used to create a high-aspect-ratio vertical channel through the stack 102, as shown in FIG. 1B. In various embodiments, the etch may be a reactive ion (gas) etch or a wet chemical etch, as discussed in more detail below. The channel width may be about 50-100 nm, with a depth of about 4-8 microns, which may be technology node and customer dependent. Although not shown, a polycrystalline Si (poly-Si) liner layer may be deposited on the stack 102 within the channel to form a poly-Si liner layer. When in operation, charge may be stored in the stack 102 (e.g., the ONON layers) and current may be carried by the poly-Si liner layer.

Note that multiple cells 100a, 100b, 100c are shown in the gapfill structure 100 of FIG. 1B. As shown, each cell 100a, 100b, 100c, may contain the stack 102, disposed on a wafer 110, and on which a field dielectric 104 is disposed.

The vertical channel with the poly-Si liner layer coating the stack 102 may be filled with a channel oxide 106 (hereinafter referred to as the channel oxide 106), such as SiO₂ for example. The channel oxide 106 may be provided to overfill (or overburden) the channel by about 30-70 nm (which may also be formed on the field dielectric 104). The overfilled structure for each cell 100a, 100b, 100c is shown in FIG. 1C.

After the channel oxide 106 is deposited, in some embodiments, the resulting structure may be planarized using a chemical mechanical planarization (CMP) process. The CMP may use a slurry and polishing apparatus appropriate to remove a portion of the oxide within the channel and the field oxide such that after planarization a top surface of the oxide within the channel and field oxide lie within the same plane.

After planarization, if used, the channel oxide 106 may then be recess etched to remove a portion of the channel oxide 106 as shown for each cell 100a, 100b, 100c in FIG. 1D. Although the channel oxide 106 may be etched by a vapor etch (e.g., using HF or XeF₂ gas), in the embodiments described herein a wet chemical etch (e.g., dilute HF (DHF) or buffered oxide etch (BOE)) may instead be used to perform the etch. Wet chemical etching is a material removal process that uses liquid chemicals or etchants to remove materials from a substrate, while vapor etch is a material removal process that uses gaseous etchants to remove materials from a layer. Patterns may be defined by photoresist masks on the substrate, and underlying material that is not protected by the mask are etched away by liquid chemicals. In some embodiments, a 100:1 DHF etch may be for about 5-60 mins to obtain a uniform recess depth from channel-to-channel (in they direction). A sufficient amount of the channel oxide 106 may be etched back from the top of the field dielectric 104, for example about 100-150 nm, although this may be customer and/or device dependent.

Thus, the stack 102 in each cell 100a, 100b, 100c may contain a channel that is filled with a channel oxide 106. Although not shown, the channels in each cell 100a, 100b, 100c may extend in the x-direction a substantial distance (e.g., for a wordline). The channels in each cell 100a, 100b, 100c may be etched simultaneously. The thermal ALD process above is used to fill the channel oxide 106 within the channel in each cell 100a, 100b, 100c, which may lead to the minimal disparity shown between different levels of channel oxide 106 in the cells 100a, 100b, 100c subsequent to etching of the channel oxide 106.

A poly-Si cap 108 may then be deposited within the channel to fill the remainder of the channel. A cap may fill or cap/seal a structure. The structure may then be planarized such that the upper surface of the poly-Si cap 108 and the field dielectric 104 lie in a plane, as shown in the final figure of FIG. 1A. Contact to the poly-Si cap 108 may be made using a metal (e.g., Al, Cu, W, Sn, Au, Ag, and/or Mo among others) to form contacts. For example, contact to the poly-Si cap 108 may result in contact to the wordlines for the 3D NAND structure.

Although a number of operations have been described in the above process, it may be desirable to drive down operational costs in semiconductor device manufacturing by, for example, increasing device yield, decreasing the number of processing steps, decreasing the amount of materials used during processing, or decreasing the amount of processing time. As shown in FIG. 1A, the resulting 3D NAND structure for a single cell may include a high-aspect-ratio channel formed using a dielectric etch. As above, various etching processes may be used to create a high-aspect-ratio channel. Each type of etching process, however, may have its own advantages and disadvantages, including sensitivity to material composition and dimensional characteristics. Even small deviations in etch rate can cause channel dimensions to differ. These deviation in etch rate may be problematic when attempting to create a high-aspect-ratio channel or when feature sizes (e.g., critical dimensions) vary from feature to feature. The critical dimension may thus be a size of a smallest feature (and may also be called linewidth or feature width). For example, while vapor/gas etch may in some cases provide a more matched etch recess than a wet etch (e.g., with a buffered oxide etch (BOE) DHF 100:1 after a recess etch), it may be more desirable to use wet chemical etching to reduce costs. The wet etch rate (WER) may depend on both the RF power and temperature used during processing. This may result in device performance variation across the wafer due to recess etch variation between the wafer center and the wafer edge without care being taken in the processing.

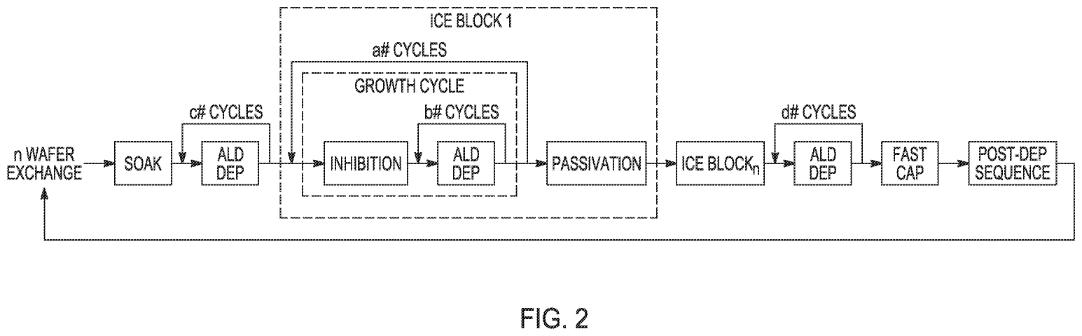

FIG. 2 is a schematic diagram showing a method of fabricating a structure, according to an example embodiment. The process 200 shown in FIG. 2 may be used to fabricate the gapfill structure shown in FIG. 1 (or the other structures described herein). The process 200 may start when one or more (e.g., as shown, n) already-processed wafers are exchanged with wafers to be processed. The wafers may be processed on a platform capable of 500-800° C. wafer processing with plasma activation for ICE-inhibition in a growth chamber. Use of a thermal ICE process method may permit fabrication of a gapfill material (oxide) with a closely matched WER performance throughout the channel and across the wafer. This may enable the recess etch depth to be matched throughout the vertical channel and across the wafer after a wet recess etch forming the channel.

The wafers moved to the pedestal may be initially brought up to the pedestal temperature in a soaking operation.

After the soaking operation, an initial deposition process may be performed. The initial deposition process may include deposition of a liner on the wafer. A sequence of layers may be grown by ALD. While in some cases, PEALD may be used to deposit the oxide, the use of PEALD may result in the compositional issues (e.g., voids) within the oxide in the high-aspect-ratio channel. Accordingly, a thermal ALD may be used to deposit the oxide. The thermal ALD process may occur at a relatively high temperature (e.g., a pedestal temperature of about 550-650° C.) compared with the PEALD process. In the thermal ALD process, the precursors may react on a heated surface of the layer of interest (e.g., Si substrate). The thermal ALD process may be carried out in a heated reactor maintained at a sub-atmospheric pressure through use of a vacuum pump and a controlled flow of inert gas, such as N₂, which may also be used for passivation. As the thermal ALD process may involve a surface reaction, the process may be self-limiting.

An initial stage of the thermal ALD process may be repeated for a first set of ALD cycles (e.g., about 150). During the first stage of the ALD process, the exposed surface of the structure may be dosed with a Si precursor (and other gasses) to permit surface reactions to occur upon deposition, after the chamber is purged. Such precursors may include aminosilane precursors, for example, Bis(tertiary-butylamino)silane (BTBAS), Diisopropylamino Silane (DIPAS), bisdi(ethylamino)silane (BDEAS), 3di(methylamine)silane (3DMAS), and tetrakis(dimethylamino)silane (4DMAS), for SiN or SiO₂ deposition. For example, H₂, O₂, Ar, N₂ and BTBAS may all be introduced to the processing chamber (the N₂ and Ar may be carrier gasses for the BTBAS and H₂ and O₂ used to form the oxide), which may be held at a low pressure. In some embodiments, for example, the processing chamber may be held at about 10-20 Torr and the pedestal on which the wafers are disposed may be maintained at about 550-650° C., into which about 3-5 L/m H₂, 3-5 L/m O₂, 20-50 L Ar, 1-3 BtBAS precursor, and 20-50 L N₂ may be introduced to generate the oxide. The pressure of the H₂ and O₂ may be increased above the injector and undergo autoignition to form a more reactive species, such as H₂O steam, H₂O₂, or O*. The use of both H₂ and O₂ may be desirable as SiO₂ growth is limited at lower temperatures without H₂ and the deposition rate at higher temperatures is substantially reduced (e.g., about half that obtained when both H₂ and O₂ are present).

In particular, after the precursor is dosed to permit surface adsorption and reaction of the precursor molecules, the chamber may be purged to remove the by-products. The precursor molecules on the surface of the structure may be converted to the desired insulator (SiN or SiO₂) by thermal oxidative activation, and then followed by another purge of the unconverted precursor molecules.

After the initial deposition process, one or more ICE block processes of the thermal ALD process may be performed. The number of ICE block processes may be a function of the feature that is fabricated. Each ICE block process may include one or more growth cycles, the last of which may be followed by passivation of the layers grown during the growth cycle. Each growth cycle may be a set of operations that result in growth of a layer. The number of growth cycles may be independent of the first number of thermal ALD cycles (i.e., the number of growth cycles may be the same as or different from the first number of ALD cycles). For example, about 10-30 growth cycles may be used in some embodiments. The number of ICE blocks, growth cycles within each ICE block and/or thermal ALD deposition cycles within each growth cycle may depend on the critical dimensions of the feature that is filled (the channel) as well as the quality of the incoming structure. For example, the number of cycles may increase with increasing channel width. The number of ICE blocks may also be increased if the structure is difficult to fill and has multiple pinch points; each ICE block is used to target each individual pinch point. That is, the number of growth cycles may be, for example, a function of the re-entrancy of the structure (i.e., the decrease in profile from the lower boundary to upper boundary/tapering, of the sidewalls of the structure). As the ALD process may deposit a (sub)angstrom thickness per cycle, control over the deposition process may be obtained at the atomic scale.

Each growth cycle may include an inhibition treatment on the topmost layer of ALD deposition of the previous growth cycle, followed by another sequence of layers grown by the thermal ALD process. The ALD deposition may be repeated a second number of ALD cycles. The second number of ALD cycles may be independent of the first number of ALD cycles and/or the number of growth cycles. For example, the second number of cycles may be about 10 cycles in some embodiments.

Inhibition may be a surface treatment that introduces one or more gasses as an inhibitor on the surface of the structure, after which the growth chamber may be purged. An inhibitor may be a substance that slows down or prevents a particular chemical reaction or other process or which reduces the activity of a particular reactant. In some embodiments, for example, the inhibitor(s) may be one or more of: Iodine (I2), HI, HF, HCl, HBr, NF₃, F₂, Cl₂, ICl₂, NCl₃, Sulfonyl halides, dials (e.g., ethane diol, ethanediol, ethylene glycol, propanediol), diamines (ethylenediamine, propylenediamine, etc.)), Acetylene, ethylene, and analogous unsaturated hydrocarbons, CO, CO₂, pyridine, piperidine, pyrrole, pyrimidine, imidazole, and/or benzene, although this list is not exclusive. In some embodiments, for example, the processing chamber may be held at about 1-10 Torr with a plasma power of about 500-2000 W, and about 3-5 L/m H₂, 0.2-2 L/m O₂, 20-50 L Ar, 0.2-0.6 L NF₃ and 20-50 L N₂ may be introduced for about 0.1-10 s (e.g., about 0.4-1 s) to provide the inhibition.

The thermal ALD deposition within the growth cycle may use characteristics similar to the initial ALD deposition. That is, in some embodiments, the processing chamber may be held at about 10-20 Torr, into which about 3-5 L/m H₂, 3-5 L/m O₂, 20-50 L Ar, 1-3 BtBAS precursor, and 20-50 L N₂ may be introduced. The ALD power may be about 2-5 kW, with the RF power on for about 0.5 s when the H₂/O₂ flows. The pedestal on which the wafers are disposed may be maintained, as above, at about 550-650° C. Each cycle time of ALD deposition in a growth cycle may be about 0.5-2.5 s.

Each ICE block may end, as above, with passivation of the structure after the growth cycles of the ICE block are completed. Passivation may be a process that renders broken bonds at a surface inactive. During passivation, residual amounts of the inhibitor deposited during each of the growth cycles of the ICE block may be removed. Passivation may be performed for tens of seconds, for example, about 40 s in some embodiments. In some embodiments, for example, the processing chamber may be held at about 1-10 Torr with a plasma power of about 500-2000 W, and about 1-5 L/m H₂, 1-5 L/m O₂, 20-50 L Ar, and 20-50 L N₂ may be introduced for about 40-120 s to passivate the structure. The pedestal on which the wafers are disposed may be maintained, as above, at about 550-650° C.

After the final ICE block process is performed, a final ALD process may be performed using similar deposition characteristics, the poly-Si cap may be deposited on the structure via PECVD, and a post-deposition sequence performed. The final ALD process may be an ALD liner deposition. The ALD sequence may be repeated a third number of ALD cycles. The third number of ALD cycles may be independent of the first number of ALD cycles, the second number of ALD cycles and/or the number of growth cycles. The post-deposition sequence may include the addition of Ar to the chamber and a reduction in the system pressure to a low base pressure (e.g., about 0.5 T), as well as any annealing and/or chemical mechanical polishing of the structure prior to removal of the wafer from the chamber. For example, an 850° C., 30 min N₂ anneal may reduce the WER and allow better depth controllability.

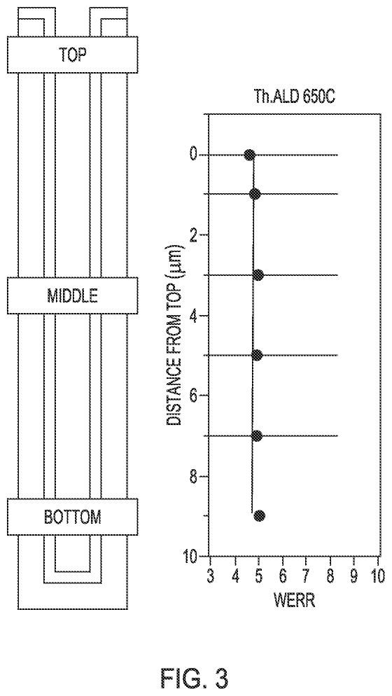

FIG. 3 is a diagram showing etch uniformity within the channel shown in FIG. 1A, according to an example embodiment. In particular, that FIG. 3 is a measurement of the wet etch rate ratio (WERR) throughout the channel. The WERR may be the wet etch rate of the oxide that is etched (i.e., the oxide in the channel) compared to thermally grown layer of the same oxide on a test wafer at a particular set of process conditions, including etchant, concentration and temperature at which the etching takes place. In FIG. 3, the WERR is the etch rate of the oxide (A/s), e.g., in 100:1 DHF/the etch rate of a high quality thermal SiO₂ grown in a furnace (A/s). As shown in FIG. 3, the WERR is constant throughout the entire depth. This may be due to the oxide having essentially a uniform film quality throughout the channel as a result of use of the thermal ALD deposition process. This is also unlike the WERR of an oxide deposited using a plasma enhanced ALD (PEALD) process, which has lower WERR at the top of the channel and higher WERR at the bottom of the channel due to difference in ion bombardment at the top vs. at the bottom of the channel (which also causes channel-to-channel variation). In addition, the WERR of a PEALD oxide in the channel, unlike the thermal ALD oxide, also may have a WERR that varies with position within the channel. That is, the PEALD oxide may have a higher WERR at center of the channel, which may cause seam blowout during the wet etch process. When tested, the etch variation may show a depth variation of <about 5% from an average etch depth across the channels, as well as a relatively constant cross-sectional area across each channel when the thermal ALD process is used (e.g., for a 130 nm target depth etch, depths that ranges from about 125-135 nm), compared with depth variations of >about 20% and a substantially ovular-shaped (or jar/bottle-shaped) cross-sectional area with one or more pinch points when the PEALD process is used.

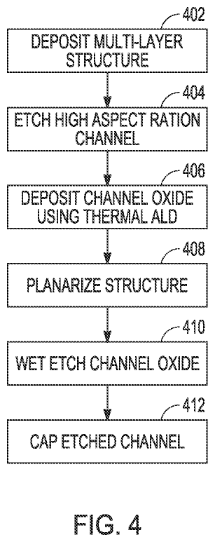

FIG. 4 shows a flowchart of fabrication of the structure shown in FIG. 1, according to an example embodiment. Only some of the operations used during the fabrication may be shown in FIG. 4.

At operation 402, a multi-layer structure may be fabricated on a Si substrate. The multi-layer structure may contain one or more of an ONON layers, OPOP layers or OMOM layers. A field oxide may be grown on the multi-layer structure.

At operation 404, a channel may be etched in the field oxide and multi-layer structure in each cell of multiple cells that span the Si substrate. Standard photolithographic processes may be used to define the channel and create the channel. The channel may be a high-aspect-ratio channel, whose depth is substantially greater than width (e.g., a factor of >about 10, such as 20). The channel may be removed via plasma etching or wet chemical etching, for example, and dependent on the composition of the layers of the multi-layer structure. A poly-Si film may be deposited within the channel so that the layers of the multi-layer structure are able to retain charge in the final structure.

At operation 406, a thermal ALD process may be used to deposit the oxide The thermal ALD process may use multiple blocks in which portions of the oxide are deposited using a precursor vapor that adsorbs on and reacts with the exposed surface. The residual precursor and reaction products may be purged, and the surface (which contains reactive oxygen radicals) exposed to a co-reactant. The co-reactant may be a H₂O for the thermal ALD process (or a low-damage plasma O₂ for PEALD) to oxidize the surface and remove surface ligands. The products of the reaction from the co-reactant may then be purged from the chamber. One or more inhibitors (e.g., NF₃) may then be provided on the uppermost layer prior to passivation of the last deposited layer of the block. The thermal ALD oxide may be less dense than a PEALD oxide. This may result in a higher magnitude wet etch rate and lower dielectric breakdown voltage.

At operation 408, the resulting structure after deposition of the oxide may be planarized through use of a chemical mechanical polishing process. In some embodiments, the resulting structure may not be planarized prior to etching the channel oxide.

At operation 410, a wet chemical etchant may be used to recess etch the oxide in the channel. For example, a DHF etch may be used to etch less than about 5% of the entire depth of the channel. The top of the etched back oxide may be either above or below the bottom of the field oxide, as desired.

After recess etching the oxide, a poly-Si cap may be deposited at operation 412 in the recess etched region. The final structure may then be planarized and removed from the chamber.

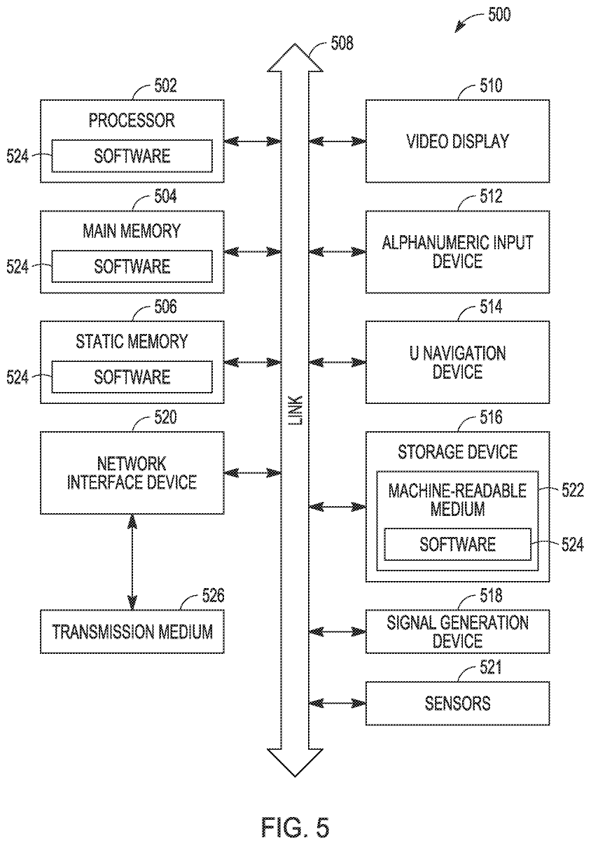

FIG. 5 is a block diagram of a machine in which the structure of FIG. 1A is incorporated, according to an example embodiment. Examples, as described herein, may include, or may operate by, logic, a number of components, or mechanisms. Circuitry may be a collection of circuits implemented in tangible entities that include hardware (e.g., simple circuits, gates, logic, etc.). Circuitry membership may be flexible over time and underlying hardware variability. Circuitry may include members that may, alone or in combination, perform specified operations during operation. In an example, hardware of the circuitry may be immutably designed to carry out a specific operation (e.g., hardwired). In an example, the hardware of the circuitry may include variably connected physical components (e.g., execution units, transistors, simple circuits, etc.). This may include a computer-readable medium physically modified (e.g., magnetically, electrically, by moveable placement of invariant massed particles, etc.) to encode instructions of the specific operation. When the physical components are connected, the underlying electrical properties of a hardware constituent may be changed (for example, from an insulator to a conductor or vice versa). The instructions may enable embedded hardware (e.g., the execution units or a loading mechanism) to create members of the circuitry in hardware via the variable connections to early out portions of the specific operation when in operation. Accordingly, the computer-readable medium may be communicatively coupled to the other components of the circuitry when the device is in operation. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 500 may include a processor 502 (e.g., a central processing unit (CPU), a hardware processor core, or any combination thereof), a graphics processing unit (GPU) (which may be part of the CPU or separate), a main memory 504, and a static memory 506, some or all of which may communicate with each other via a link (e.g., bus) 508. The machine 500 may further include a display 510, an alphanumeric input device 512 (e.g., a keyboard), and a user interface (UI) navigation device 514 (e.g., a mouse). In an example, the display 510, alphanumeric input device 512, and UI navigation device 514 may be a touch screen display. The machine 500 may additionally include a storage device (e.g., drive unit) 516, a signal generation device 518 (e.g., a speaker), a network interface device 520, and one or more sensors 521, such as a Global Positioning System (GPS) sensor, compass, accelerometer, or another sensor. The machine 500 may include transmission medium 526, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The storage device 516 may include a machine-readable medium 522 on which is stored one or more sets of data structures or instructions 524 (referred to as software) that embody or are utilized by any one or more of the techniques or functions described herein. The instructions 524 may also reside, completely or at least partially, within the main memory 504, within the static memory 506, within the processor 502, or within the GPU, during execution thereof by the machine 500. In an example, one or any combination of the processor 502, the GPU, the main memory 504, the static memory 506, or the storage device 516 may constitute machine-readable media.

While the machine-readable medium 522 is illustrated as a single medium, the term “machine-readable medium” may include a single medium or multiple media (e.g., a centralized or distributed database, and/or associated caches and servers) configured to store the one or more instructions 524. The term “machine-readable medium” may include any medium that can store, encode, or carry the instructions 524 for execution by the machine 500 and that cause the machine 500 to perform any one or more of the techniques of the present disclosure, or that can store, encode, or carry data structures used by or associated with such instructions 524. Non-limiting machine-readable medium examples may include solid-state memories, and optical and magnetic media. In an example, a massed machine-readable medium comprises a machine-readable medium 522 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks. The instructions 524 may further be transmitted or received over a communications network through a transmission medium 526 via the network interface device 520.

The processor 502, in conjunction with the main memory 504 and static memory 506, may thus be used to operate the cleaning apparatus described. One or more of the main memory 504 and static memory 506 may include the 3D NAND device shown in FIG. 1A. The display 510, alphanumeric input device 512, UI navigation device 514, and signal generation device 518 may be used to notify the operator as to processes of the cleaning, including completion or errors, as well as approximate amount of removal for each cleaning apparatus, perhaps using the sensors 521. The information may be provided to an operator (e.g., mobile device of the operator) via the network interface device 520. All of the mechanisms may be controlled when the instructions are 524 are executed by the processor 502.

Example 1 is a method of fabricating a semiconductor device, the method comprising: etching high-aspect-ratio channels in a multi-layer stack disposed on a semiconductor substrate, the multi-layer stack comprising sets of oxide and non-oxide layers; filling each of the high-aspect-ratio channels with an oxide using a thermal atomic layer deposition (ALD) process; recess etching the oxide using a wet chemical etch to form recess-etched channels; and capping the recess-etched channels to refill an etched portion of the recess-etched channels with a conductive material.

In Example 2, the subject matter of Example 1 includes that filling each of the high-aspect-ratio channels with an oxide comprises: depositing a silicon (Si) oxide in multiple blocks that each contains multiple growth cycles followed by a passivation operation, each of the growth cycles including: introduction of an inhibitor into a chamber in which the semiconductor substrate is disposed during an inhibition operation, followed by multiple thermal ALD deposition cycles.

In Example 3, the subject matter of Example 2 includes injecting H₂, O₂, Ar, and N₂ gasses and an aminosilane precursor during each ALD deposition cycle to deposit a sub-angstrom thickness of oxide per ALD deposition cycle.

In Example 4, the subject matter of Examples 2-3 includes that the inhibitor includes multiple gasses that each act as an inhibitor.

In Example 5, the subject matter of Example 4 includes that the inhibition operation is maintained for less than about 1 s.

In Example 6, the subject matter of Examples 2-5 includes maintaining a temperature of a pedestal on which the semiconductor substrate is disposed during the growth cycle of about 550-650° C. and a pressure in the chamber of about 10-20 Torr.

In Example 7, the subject matter of Examples 2-6 includes injecting H₂, O₂, Ar, and N₂ gasses during each passivation operation to remove residual inhibitor and passivate an exposed surface of the Si oxide in each of the high-aspect-ratio channels, the passivation operation maintained for up to about two minutes.

In Example 8, the subject matter of Examples 2-7 includes purging the chamber of gasses used in each growth cycle after the inhibition operation, before and after the thermal ALD deposition cycles associated with the inhibition operation, and after the passivation operation.

In Example 9, the subject matter of Examples 2-8 includes that filling each of the high-aspect-ratio channels with a Si oxide further comprises: depositing a first thermal Si oxide ALD liner layer within each of the high aspect-ratio-channels to form a liner layer prior to depositing the Si oxide in a first of the blocks; and depositing a second thermal Si oxide ALD liner layer after depositing the Si oxide within each of the high-aspect-ratio channels after last of the blocks.

In Example 10, the subject matter of Examples 2-9 includes, for filling each of the high-aspect-ratio channels with the Si oxide: determining a number of blocks, a number of growth cycles within each block and a number of thermal ALD deposition cycles within each growth cycle, at least one of which depends on critical dimensions of each of the high-aspect-ratio channels as well as a quality of a structure in which the Si oxide is to be deposited.

In Example 11, the subject matter of Examples 1-10 includes that recess etching the oxide includes etching the oxide using a dilute HF (DHF) etch of about 100:1 HF:H₂O, the oxide having a relatively constant etch rate along a width and depth of each of the high-aspect-ratio channels.

In Example 12, the subject matter of Examples 1-11 includes that capping the recess-etched channels includes: depositing polycrystalline Si (poly-Si) in the recess-etched channels using plasma-enhanced chemical vapor deposition.

In Example 13, the subject matter of Example 12 includes growing a field oxide on the multi-layer stack prior to forming the high-aspect-ratio channels; and planarizing the poly-Si to expose the field oxide, a top surface of the field oxide and a top surface of the poly-Si in each of the high-aspect-ratio channels lying in a plane after planarization of the poly-Si.

In Example 14, the subject matter of Example 13 includes depositing a sufficient amount of the oxide to cover the field oxide; and planarizing the oxide prior to recess etching the oxide such that a top surface of the field oxide and a top surface of the oxide in each of the high-aspect ratio-channels lie in a plane after planarization of the oxide.

In Example 15, the subject matter of Examples 1-14 includes depositing alternating SiO2 and SiN layers as the multi-layer stack.

In Example 16, the subject matter of Examples 1-15 includes wherein: the recess etching of the oxide avoids etching of the oxide using a vapor etch.

Example 17 is a NAND device comprising: a multi-layer stack disposed on a semiconductor substrate, the multi-layer stack including pairs of layers of alternating materials, the multi-layer stack including a plurality of high-aspect-ratio channels disposed therein; a field oxide disposed on the multi-layer stack; a thermal atomic layer deposition (ALD) Silicon (Si) oxide disposed within each of the high-aspect-ratio channels, the Si oxide etched such that a surface of the Si oxide is beneath the field oxide; and a polycrystalline Si (poly-Si) cap disposed within each of the high-aspect-ratio channels on the Si oxide.

In Example 18, the subject matter of Example 17 includes that the pairs of layers of the multi-layer stack comprise a SiO2 layer and a SiN layer.

In Example 19, the subject matter of Examples 17-18 includes that a depth of each of the high-aspect-ratio channels is between about 4 and about 8 microns and a width of each of the high-aspect-ratio channels is between about 50 nm and 100 nm.

In Example 20, the subject matter of Examples 17-19 includes that a depth of the poly-Si cap in each of the high-aspect-ratio channels is about 1-4% of a depth of the high-aspect-ratio channels.

Example 21 is a method of fabricating a semiconductor device, the method comprising: etching high-aspect-ratio channels in a multi-layer stack disposed on a semiconductor substrate, the multi-layer stack comprising sets of silicon (Si) oxide and non-Si oxide layers; depositing, in the high-aspect-ratio channels until each of the high-aspect-ratio channels is filled, a channel oxide in multiple blocks that each contains multiple growth cycles followed by a passivation operation, each of the growth cycles comprising: introducing an inhibitor into a chamber in which the semiconductor substrate is disposed during an inhibition operation, and multiple thermal atomic layer deposition (ALD) deposition cycles; recess etching the channel oxide to form recess-etched channels; and capping each of the recess-etched channels with a cap to refill an etched portion of the recess-etched channels with a conductive material.

In Example 22, the subject matter of Example 21 includes depositing a first thermal Si oxide ALD liner layer within each of the high aspect-ratio-channels to form a liner layer prior to depositing the Si oxide in a first of the blocks; and depositing a second thermal Si oxide ALD liner layer after depositing the Si oxide within each of the high-aspect-ratio channels after a last of the blocks.

In Example 23, the subject matter of Examples 21-22 includes growing a field oxide on the multi-layer stack prior to forming the high-aspect-ratio channels; and planarizing the cap to expose the field oxide, a top surface of the field oxide and a top surface of the cap in each of the high-aspect-ratio channels lying in a plane after the planarization.

Example 24 is at least one machine-readable medium including instructions that, when executed by processing circuitry, cause the processing circuitry to perform operations to implement of any of Examples 1-23.

Example 25 is an apparatus comprising means to implement of any of Examples 1-23.

Example 26 is a system to implement of any of Examples 1-23.

While exemplary aspects of the subject matter discussed herein have been shown and described herein, it will be obvious to those skilled in the art that such embodiments are provided by way of example only. Numerous variations, changes, and substitutions will now occur to those skilled in the art, upon reading and understanding the material provided herein, without departing from the scope of the disclosed subject matter. It should be understood that various alternatives to the embodiments of the disclosed subject matter described herein may be employed in practicing the various embodiments of the subject matter.

Accordingly, the specification and drawings are to be regarded in an illustrative rather than a restrictive sense. The accompanying drawings that form a part hereof show, by way of illustration, and not of limitation, specific aspects in which the subject matter may be practiced. The aspects illustrated are described in sufficient detail to enable those skilled in the art to practice the teachings disclosed herein. Other aspects may be utilized and derived therefrom, such that structural and logical substitutions and changes may be made without departing from the scope of this disclosure. This Detailed Description, therefore, is not to be taken in a limiting sense, and the scope of various aspects is defined only by the appended claims, along with the full range of equivalents to which such claims are entitled. It is intended that the following claims define the scope of the disclosed subject matter and that methods and structures within the scope of these claims and their equivalents be covered thereby.

The abstract will allow the reader to quickly ascertain the nature of the technical disclosure. The abstract is submitted with the understanding that it will not be used to interpret or limit the scope or meaning of the claims. In addition, in the foregoing Detailed Description, it can be seen that various features are grouped together in a single aspect for the purpose of streamlining the disclosure, This method of disclosure is not to be interpreted as reflecting an intention that the claimed aspects make use of more features than are expressly recited in each claim. Rather, as the following claims reflect, inventive subject matter lies in less than all features of a single disclosed aspect. Thus, the following claims are hereby incorporated into the Detailed Description, with each claim standing on its own as a separate aspect.

1. A method of fabricating a semiconductor device, the method comprising:
etching high-aspect-ratio channels in a multi-layer stack disposed on a semiconductor substrate, the multi-layer stack comprising sets of oxide and non-oxide layers;
filling each of the high-aspect-ratio channels with an oxide using a thermal atomic layer deposition (ALD) process;
recess etching the oxide using a wet chemical etch to form recess-etched channels; and
capping the recess-etched channels to refill an etched portion of the recess-etched channels with a conductive material.

2. The method of claim 1, wherein filling each of the high-aspect-ratio channels with an oxide includes:
depositing a silicon (Si) oxide in multiple blocks that each contains multiple growth cycles followed by a passivation operation, each of the growth cycles including: introduction of an inhibitor into a chamber in which the semiconductor substrate is disposed during an inhibition operation, followed by multiple thermal ALD deposition cycles.

3. The method of claim 2, further comprising injecting H₂, O₂, Ar, and N₂ gasses and an aminosilane precursor during each ALD deposition cycle to deposit a sub-angstrom thickness of oxide per ALD deposition cycle.

4. The method of claim 2, wherein the inhibitor includes multiple gasses that each act as an inhibitor and the inhibition operation is maintained for less than about 1 s.

5. The method of claim 1, wherein recess etching the oxide includes etching the oxide using a dilute HF (DHF) etch of about 100:1 HF:H₂O, the oxide having a relatively constant etch rate along a width and depth of each of the high-aspect-ratio channels.

6. The method of claim 2, further comprising maintaining, during the growth cycle, a temperature of a pedestal on which the semiconductor substrate is disposed of about 550-650° C. and a pressure in the chamber of about 10-20 Torr.

7. The method of claim 2, further comprising injecting H₂, O₂, Ar, and N₂ gasses during each passivation operation to remove residual inhibitor and passivate an exposed surface of the Si oxide in each of the high-aspect-ratio channels, the passivation operation maintained for up to about two minutes.

8. The method of claim 2, further comprising purging the chamber of gasses used in each growth cycle:
after the inhibition operation,
before and after the thermal ALD deposition cycles associated with the inhibition operation, and
after the passivation operation.

9. The method of claim 2, wherein filling each of the high-aspect-ratio channels with an oxide includes:
depositing a first thermal Si oxide ALD liner layer within each of the high aspect-ratio-channels to form a liner layer prior to depositing the Si oxide in a first of the blocks; and
depositing a second thermal Si oxide ALD liner layer after depositing the Si oxide within each of the high-aspect-ratio channels after a last of the blocks.

10. The method of claim 2, further comprising, for filling each of the high-aspect-ratio channels with the Si oxide:
determining a number of blocks, a number of growth cycles within each block and a number of thermal ALD deposition cycles within each growth cycle, at least one of which depends on critical dimensions of each of the high-aspect-ratio channels as well as a quality of a structure in which the Si oxide is to be deposited.

11. The method of claim 1, further comprising depositing alternating SiO₂ and SiN layers as the multi-layer stack.

12. The method of claim 1, wherein capping the recess-etched channels includes depositing polycrystalline Si (poly-Si) in the recess-etched channels using plasma-enhanced chemical vapor deposition.

13. The method of claim 12, further comprising:
growing a field oxide on the multi-layer stack prior to forming the high-aspect-ratio channels; and
planarizing the poly-Si to expose the field oxide, a top surface of the field oxide and a top surface of the poly-Si in each of the high-aspect-ratio channels lying in a plane after planarization of the poly-Si.

14. The method of claim 13, further comprising:
depositing an amount of the oxide sufficient to cover the field oxide; and
planarizing the oxide prior to recess etching the oxide such that a top surface of the field oxide and a top surface of the oxide in each of the high-aspect ratio-channels lie in a plane after planarization of the oxide.

15. A method of fabricating a semiconductor device, the method comprising:
etching high-aspect-ratio channels in a multi-layer stack disposed on a semiconductor substrate, the multi-layer stack comprising sets of silicon (Si) oxide and non-Si oxide layers;
depositing, in the high-aspect-ratio channels until each of the high-aspect-ratio channels is filled, a channel oxide in multiple blocks that each contains multiple growth cycles followed by a passivation operation, each of the growth cycles comprising:
introducing an inhibitor into a chamber in which the semiconductor substrate is disposed during an inhibition operation, and
multiple thermal atomic layer deposition (ALD) deposition cycles;
recess etching the channel oxide to form recess-etched channels; and
capping each of the recess-etched channels with a cap to refill an etched portion of the recess-etched channels with a conductive material.

16. The method of claim 15, further comprising:
depositing a first thermal Si oxide ALD liner layer within each of the high aspect-ratio-channels to form a liner layer prior to depositing the Si oxide in a first of the blocks; and
depositing a second thermal Si oxide ALD liner layer after depositing the Si oxide within each of the high-aspect-ratio channels after a last of the blocks.

17. The method of claim 15, further comprising:
growing a field oxide on the multi-layer stack prior to forming the high-aspect-ratio channels; and
planarizing the cap to expose the field oxide, a top surface of the field oxide and a top surface of the cap in each of the high-aspect-ratio channels lying in a plane after the planarization.

18. A NAND device comprising:
a multi-layer stack disposed on a semiconductor substrate, the multi-layer stack comprising pairs of layers of alternating materials, the multi-layer stack comprising a plurality of high-aspect-ratio channels disposed therein;
a field oxide disposed on the multi-layer stack;
a thermal atomic layer deposition (ALD) Silicon (Si) oxide disposed within each of the high-aspect-ratio channels, the Si oxide etched such that a surface of the Si oxide is beneath the field oxide; and
a polycrystalline Si (poly-Si) cap disposed within each of the high-aspect-ratio channels on the Si oxide.

19. The NAND device of claim 18, wherein the pairs of layers of the multi-layer stack includes a SiO₂ layer and a SiN layer.

20. The NAND device of claim 18, wherein at least one of:
a depth of each of the high-aspect-ratio channels is between about 4 and about 8 microns and a width of each of the high-aspect-ratio channels is between about 50 nm and 100 nm, or
a depth of the poly-Si cap in each of the high-aspect-ratio channels is about 1-4% of a depth of the high-aspect-ratio channels.
